(19) United States
(12) Patent Application Publication
(10) Pub. No.: US 2008/0289690 A1
(43) Pub. Date: Nov. 27, 2008

(54) Process For Producing a Silicon Film on a Substrate Surface By Vapor Deposition

(75) Inventors: Raymund Sonnenschein, Frankfurt am Main (DE); Hartwig Rauleder, Rheinfelden (DE); Hans Juergen Hoene, Bad Nauheim (DE); Stefan Reber, Gundelfingen (DE); Norbert Schillinger, Ihringen (DE)

Correspondence Address: OBLON, SPIVAK, MCCLELLAND MAIER & NEUSTADT, P.C., 1940 DUKE STREET, ALEXANDRIA, VA, 22314, US

(73) Assignees: EVONIK DEGUSSA GmbH, Essen (DE); FRAUNHOFER-GESELL. ZUR FOERD DER ANG. FORS. E.V., Muenchen (DE)

(21) Appl. No.: 12/097,645

(22) PCT Filed: Dec. 7, 2006
(86) PCT No.: PCT/EP06/69405

§ 371 Date: Jun. 16, 2008

(30) Foreign Application Priority Data
Jan. 25, 2006 (DE) 102006003464.3

(51) Int. Cl. H01L 31/0264; H01L 31/18; C23C 16/42

(52) U.S. Cl. 136/261; 427/255.17

(57) ABSTRACT

The present invention relates to a process for producing a silicon film on a substrate surface by vapor deposition, starting from a silicon-based precursor, characterized in that the precursor used is silicon tetrachloride. The present invention also relates to thin-film solar cells or crystalline silicon thin-film solar cells obtainable by the process according to the invention. The invention also relates to the use of silicon tetrachloride for producing a film deposited on a substrate from the vapor phase.

The invention relates to a process for producing a silicon film on a substrate surface by vapor deposition, starting from a silicon-based precursor. The present invention also relates to solar cells and to a new use of silicon tetrachloride.

There is an ongoing pressure to produce less and less expensive solar cells.

The basic structure of a solar cell generally involves a base contact, an electrically active absorber film, which may be applied to a substrate that is not suitable for direct processing of solar cells, an emitter layer, to which the emitter contact is applied, and an antireflection/passivation coating, to which the emitter contact is applied.

Currently, the leading type of solar cell, i.e. what is known as the silicon wafer solar cell, comprises a 200 to 300 μm thick Si wafer. In addition to the considerable consumption of silicon required for this wafer, production involves considerable quantities of silicon which are lost as waste.

Crystalline silicon thin-film solar cells (CSTF solar cells) combine the advantages of “conventional” silicon wafer solar cells and thin-film solar cells. The absorber film of crystalline silicon is only 5 to 40 μm thick and is applied to an inexpensive substrate.

There are no sawing losses of expensive, high-purity silicon. Therefore, CSTF solar cells are a promising alternative for cost-saving production of solar cells.

The production of CSTF solar cells still involves a step of depositing a thin silicon film, usually via the vapor phase.

It has long been known that silicon can be deposited on a substrate in the form of a thin film by the decomposition of a metal compound in gas or vapor form, i.e. using a CVD process (CVD=Chemical Vapor Deposition). Examples of particular deposition technologies include the PECVD (Plasma-Enhanced Chemical Vapor Deposition) and “Hot Wire Deposition” processes.

Silicon-containing carrier gases (precursors) are used. These are usually monosilane (SiH₄), dichlorosilane (H₂SiCl₂) or trichlorosilane (HSiCl₃). A drawback of these compounds is that they are combustible or even self-ignitable, in particular in the case of monosilane. Consequently, complex and expensive safety measures have to be taken when using these compounds on an industrial scale.

The present invention is based on the object of providing a further way of depositing thin silicon films on a substrate surface, in particular for the production of solar cells.

According to the invention, the object was achieved in accordance with the details given in the patent claims.

Surprisingly, it has been discovered that thin silicon films can be deposited from the vapor phase on a substrate surface in a simple and economical way, in particular for the production of solar cells, if the precursor used is silicon tetrachloride, preferably high-purity SiCl₄.

The use according to the invention of silicon tetrachloride as precursor instead of monosilane, dichlorosilane or trichlorosilane allows associated drawbacks to be avoided.

For example, the financial, technical and staff outlay for transport, storage and disposal of precursors are considerably reduced compared to the prior art, so that films produced in accordance with the invention can overall be deposited in a much more favorable way.

This advantage is particularly significant in the case of relatively thick films, since in these cases the costs of the precursor gases dominate the deposition costs.

Furthermore, if SiCl₄ is used, the technical quality of the silicon films deposited in accordance with the invention, for photovoltaics purposes, is in every respect of comparable quality to systems obtained using for example HSiCl₃.

Solar cells obtained in accordance with the invention also achieve a good efficiency which is in all respects the equal of prior art solar cells. However, on account of the use of SiCl₄, solar cells obtainable in accordance with the invention can be produced at significantly lower cost and are therefore more advantageous than prior art solar cells.

Therefore, the subject matter of the present invention is a process for producing a silicon film on a substrate surface by vapor deposition, starting from a silicon-based precursor, characterized in that the precursor used is silicon tetrachloride.

Installations or apparatuses which are known per se, for example commercially available reactors for single wafers or batch operation, or reactors which have been specially developed for photovoltaics, such as the ConCVD presented by Hurrle et al. [A. Hurrle, S. Reber, N. Schillinger, J. Haase, J. G. Reichart, High Throughput Continuous CVD Reactor for Silicon Depositions, in Proc. 19^{th} European Conference on Photovoltaic Energy Conversion, J.-L. Bal W. Hoffmann, H. Ossenbrink, W. Palz, P. Helm (Eds.), (WIP-Munich, ETA-Florence), 459 (2004)], can be used to carry out the process according to the invention.

The procedure in the process according to the invention is preferably that
high-purity silicon tetrachloride is vaporized, if appropriate together with one or more further precursors selected from the group consisting of the chlorides and/or hydrides, and
is mixed with a carrier gas, preferably argon and/or hydrogen,
the gas mixture, in a reaction chamber, is brought into contact with the substrate that is to be coated and in the reaction chamber has been heated to a temperature of 900 to 1390° C., preferably from 1100 to 1250° C.,
a thin, if appropriate doped silicon film is deposited on the substrate surface, and
the volatile by-products of the reaction are discharged from the reaction chamber.

In this case, the procedure adopted can be that first of all precursors and carrier gases are mixed prior to the deposition step and fed to the reaction space. However, the procedure may also involve feeding precursors and carrier gases to the reaction chamber separately, in which case they are mixed in the reaction chamber and come into contact with the hot substrate.

Furthermore, the vapor deposition can be carried out by thermal decomposition of high-purity silicon tetrachloride at a pressure of 0.8 to 1.2 bar abs., preferably at atmospheric pressure.

Furthermore, it may be preferable for the gas mixture of carrier gas and precursors to have a mean residence time in the reaction chamber of 0.05 to 5 seconds, preferably 0.1 to 1 second.

For deposition, the substrate in the reaction chamber is preferably heated thermally, electrically or by irradiation (lamp heating), i.e. is brought to a temperature suitable for decomposition of the precursor.

It is preferable for the substrate that is to be coated, in particular—although not exclusively—for the production of CSTF solar cells, to be exposed to the reaction conditions in the reaction chamber for a period of 2 to 30 minutes, preferably 5 to 10 minutes.

In this case, it is preferable to deposit an epitaxial silicon film at 2000 to 6000 nm per minute.

In the process according to the invention, it is advantageous to deposit an epitaxial silicon film on the substrate surface, preferably a homo-epitaxial film. Therefore, according to the invention, the vapor deposition can be carried out to produce a thin silicon film, in particular with a thickness from 10 to 50 000 nm, preferably from 500 to 40 000 nm, with the ranges from 1 to 8 μm and 15 to 25 μm being particularly preferred, on a multicrystalline or amorphous silicon substrate surface, and can advantageously be used to produce thin-film solar cells or crystalline silicon thin-film solar cells. However, the deposition can also be carried out on other, substantially thermally stable substrates.

Furthermore, in the process according to the invention, the precursor used may preferably be SiCl₄ mixed with at least one chlorine or hydrogen compound, which can be converted to the vapor phase, selected from the elements from the third, fourth or fifth main group of the periodic system of the elements, preferably a chloride of boron, germanium, phosphorus, or corresponding hydrides, for example diborane or phosphine.

Furthermore, a substrate which has been coated in accordance with the invention can be processed further to form a solar cell.

For this purpose, the coated substrate can, in a manner known per se, first of all
be cleaned and textured, for example using a hot KOH/isopropanol/H₂O solution or by plasma-chemical means,
then diffused out of the vapor phase or another dopant source at 800 to 1000° C., for example using POCl₃,
the glass layer formed during the diffusion can be removed, for example using hydrofluoric acid,
a thin antireflection coating, for example of SiNₓ:H, can be deposited on the electronically active silicon film, and
then the metal contacts can be printed on the front and back surfaces using screen printing and alloyed in using a temperature step.

By way of example, although not exclusively, however, the following procedure can also be adopted:
etching with an acid or alkali,
followed by diffusion out of the vapor phase using POCl₃ at 800 to 850° C.,
removal of the phosphorus glass formed during the diffusion by means of hydrofluoric acid,
growth of a thin passivation oxide on the electronically active silicon film,
then defining the metal contact on the emitter in a lithographic working step and applying it by evaporation coating with a metallic, electrically conductive layer system, preferably comprising Ti, Pd and Ag and using the lift-off process, and
then advantageously producing the base contact on the back surface of the coated substrate by evaporation coating with aluminum, preferably with a film thickness of approx. 200 nm.
in addition, an antireflection coating can then be applied, for example comprising titanium dioxide and magnesium fluoride.

In general terms, the present invention is carried out in the following way:

A substrate to be coated is generally pretreated by wet-chemical means, as described above, and is usually introduced into a reaction chamber, purged with argon or hydrogen and heated to a temperature which is suitable for decomposition of a precursor. SiCl₄ is suitably vaporized, if appropriate doped and mixed with argon and/or hydrogen, for example in a molar ratio of 1 to 100% SiCl₄ with respect to hydrogen. The gas mixture can then be fed to the reaction chamber, where a silicon film is deposited on the surface of the heated substrate. The present method is expediently operated at atmospheric pressure. However, it may also be carried out at reduced or elevated pressure. Reaction by-products which form are generally discharged and discarded. The substrate which has been coated in this way can also advantageously be used, in a manner known per se, for the production of solar cells.

Therefore, the subject matter of the present invention also encompasses crystalline silicon thin-film solar cells obtainable by the process according to the invention.

A further subject matter of the present invention is the use of silicon tetrachloride for producing a film deposited on a substrate from the vapor phase, preferably an epitaxial silicon film, which is advantageously obtainable by the process according to the invention. The film may be an undoped or doped silicon film.

Silicon tetrachloride can advantageously also be used for producing a film based on silicon on a substrate selected from the group consisting of SiC, SiNₓ, SiOₓ, in each case with x=0.1 to 2, or on silicon, for example on a silicon wafer, by means of vapor deposition.

Therefore, the subject matter of the present invention is also the use according to the invention of silicon tetrachloride for the production of thin-film solar cells or crystalline silicon thin-film solar cells, which may advantageously be provided epitaxially with a doped or undoped silicon film.

1: A process for producing a silicon film on a substrate surface by vapor deposition, starting from a silicon-based precursor,
wherein
the precursor used is silicon tetrachloride.

2: The process according to claim 1,
wherein
high-purity silicon tetrachloride is vaporized, optionally together with one or more further precursors selected from the group consisting of chlorides and/or hydrides, and
is mixed with a carrier gas to form a gas mixture,
the gas mixture, in a reaction chamber, is brought into contact with the substrate that is to be coated and, in the reaction chamber, has been heated to a temperature of 900 to 1390° C.,
a thin, optionally doped, silicon film is deposited on the substrate surface, and
volatile by-products of the reaction are discharged from the reaction chamber.

3: The process according to claim 1,
wherein
the vapor deposition is carried out by thermal decomposition of high-purity silicon tetrachloride at a pressure from 0.8 to 1.2 bar abs.

4: The process according to claim 2,
wherein the gas mixture and precursor remains in the reaction chamber for a mean residence time of 0.05 to 5 seconds.

5: The process according to claim 1,
wherein the vapor deposition for producing a thin silicon film is carried out on a multicrystalline silicon substrate surface.

6: The process according to claim 2,
wherein the substrate is heated in the reaction chamber either thermally, electrically or by irradiation.

7: The process according to claim 2,
wherein the substrate that is to be coated is exposed to reaction conditions in the reaction chamber for a period of 2 to 30 minutes.

8: The process according to claim 1,
wherein during the vapor deposition an epitaxial silicon film is deposited on the substrate surface.

9: The process according to claim 1,
wherein an epitaxial silicon film is deposited at 2000 to 6000 nm per minute.

10: The process according to claim 1,
wherein the precursor used is SiCl₄ mixed with at least one chlorine compound or hydrogen compound, which can be converted into the vapor phase, the chlorine compound or the hydrogen compound comprising an element selected from the third, fourth or fifth main group of the periodic system of the elements.

11: The process according to claim 1,
wherein the substrate, which has been coated, is processed further to form a solar cell.

12: The process according to claim 11,
wherein the coated substrate
is cleaned or textured,
then diffused out of the vapor phase or another dopant source at 800 to 1000° C.,
a glass layer formed during the diffusion is removed,
a thin antireflection coating is deposited on the electronically active silicon film, and
then metal contacts are alloyed in on the front and back surfaces of the coated substrate by screen printing using a temperature step.

13: A thin-film solar cell or a silicon thin-film solar cell, obtained by the process according to claim 1.

14: A film deposited on a substrate from the vapor phase, obtained by the process according to claim 1.

15: The film according to claim 14, wherein the film is deposited epitaxially from the vapor phase on the substrate.

16: The film according to claim 14, wherein the film is an undoped or doped silicon film on the substrate by means of vapor deposition.

17: The film according to claim 14, wherein the substrate is selected from the group consisting of SiC, SiNₓ, SiOₓ, in each case with x=0.1 to 2.

18: The film according to claim 14, wherein the film is a silicon film deposited on a substrate comprising silicon by means of vapor deposition.

19: Thin-film solar cells or crystalline silicon thin-film solar cells comprising the film according to claim 14.

20: The crystalline silicon thin-film solar cell or the thin-film solar cell according to claim 19, wherein said crystalline silicon thin-film solar cell or said thin-film solar cell is provided epitaxially with a doped or undoped silicon film.
